(19) United States
(12) Patent Application Publication
(10) Pub. No.: US 2026/0239676 A1
(43) Pub. Date: Aug. 13, 2026

(54) Superjunction-JFET, Method for Producing a Superjunction-JFET and Electronic Circuit

(71) Applicant: Infineon Technologies Austria AG, Villach (AT)

(72) Inventors: Hans Weber, Villach (AT); Matteo-Alessandro Kutschak, Ludmannsdorf (AT); Andreas Riegler, Wernberg (AT); Daniel Tutuc, Villach (AT)

(21) Appl. No.: 19/156,196

(22) PCT Filed: Feb. 14, 2024
(86) PCT No.: PCT/EP2024/053688

§ 371 Date: Aug. 13, 2025

(30) Foreign Application Priority Data
Feb. 15, 2023 (EP) 23156943.5

(51) Int. Cl. H10D 30/83; H10D 30/01; H10D 62/10; H10D 62/832

(52) U.S. Cl. CPC H10D 30/831; H10D 30/0515; H10D 62/111; H10D 62/8325

(57) ABSTRACT

A superjunction JFET, a method for producing a superjunction JFET, and an electronic circuit including a superjunction JFET are disclosed. The superjunction JFET has a threshold voltage and a depletion voltage. According to one example, the depletion volt-age is lower than 4 times of the magnitude of the threshold voltage. According to an-other example, the depletion voltage is less than 40 V or less than 30 V.

### TECHNICAL FIELD

This description generally relates to a superjunction JFET and an electronic circuit with a superjunction JFET.

### BACKGROUND

A superjunction JFET is a JFET (Junction Field-Effect Transistor) operating in accordance with the compensation principle. A superjunction JFET includes a drift region in which N-doped and P-doped semiconductor regions are arranged next to each other. The N-doped and P-doped regions mutually deplete each other when the device is in a blocking state.

### SUMMARY

One example relates to a superjunction JFET having a threshold voltage and a depletion voltage, wherein a magnitude of the depletion voltage is lower than 4 times of the magnitude of the threshold voltage.

Another example relates to a superjunction JFET having a depletion voltage that is less than 40 V. According to one example, the depletion voltage is less than 30 V.

Another example relates to an electronic circuit that includes a superjunction JFET in accordance with one of these examples and that further includes an electronic switch connected in series with a drain-source path of the superjunction JFET, and an inductive circuit connected in parallel with the drain-source path of the superjunction JFET.

Yet another example relates to a method. The method includes forming implantation trenches in a semiconductor body such that the trenches are spaced apart from each other in a first lateral direction of the semiconductor body and separated from each other by semiconductor mesa regions, forming a first region of a first doping type in each of the mesa regions using a first implantation process, forming a second region of a second doping type complementary to the first doping type using a second implantation process, filling the implantation trenches with a monocrystalline semiconductor material in an epitaxial growth process The method further includes, forming gate trenches in the semiconductor body, forming third regions of the second doping type along sidewalls of the gate trenches and fourth regions of the second doping type along the bottoms of the gate trenches such that each second region adjoins at least one third region or fourth region, and forming gate electrodes in the gate trenches.

Examples are explained below with reference to the drawings. The drawings serve to illustrate certain principles, so that only aspects necessary for understanding these principles are illustrated. The drawings are not to scale. In the drawings the same reference characters denote like features.

### BRIEF DESCRIPTION OF THE DRAWINGS

FIG. 1 illustrates a circuit symbol of a superjunction JFET;

FIG. 2 illustrates the characteristic curve of an output capacitance of a superjunction device;

FIG. 3 illustrates an application circuit of a superjunction JFET according to FIG. 1;

FIG. 4 schematically illustrates a cross-sectional view of a section of a superjunction JFET;

FIG. 5 schematically illustrates doping concentrations in the JFET according to FIG. 4 along line A-A′ illustrated in FIG. 4;

FIG. 6 illustrates an effective doping concentration (net doping concentration) along the line A-A′ illustrated in FIG. 4;

FIG. 7 illustrates a horizontal electric field along the line A-A′ illustrated in FIG. 4 when the JFET is blocking; and

FIGS. 8A-8D illustrate one example of a method for forming a superjunction JFET of the type illustrated in FIG. 4.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

FIG. 1 illustrates a circuit symbol of a superjunction JFET 1 and illustrates internal capacitances of the JFET. The superjunction JFET includes a drive input for applying a drive voltage Vgs. In the example illustrated in FIG. 1, the drive input is formed by a gate terminal (gate node) G and a source terminal (source node) S of the JFET. The JFET further includes a load path which extends between a first load path terminal (first load path node) and a second load path node terminal (second load path node). In the example illustrated in FIG. 1, the first load path terminal is a drain terminal D and the second load path terminal is the source terminal S of the JFET.

The JFET is conducting or blocking dependent on a voltage level of the drive voltage Vgs. The JFET is conducting when the drive voltage Vgs is higher than a threshold voltage and is blocking when the drive voltage is lower than the threshold voltage. An operating state in which the JFET is conducting is referred to as conducting state and an operating state in which the JFET is blocking is referred to as blocking state in the following.

The JFET is in the conducting state when a voltage Vds is applied across the load path and a load current Ids flows through the load path. In this context, a load current Ids flowing through the load path in the conducting state is a current that is higher than a leakage current that may flow through the load path when the JFET is in the blocking state. According to one example, the drive voltage Vgs equals the threshold voltage, so that the JFET enters the conducting state, when the load current reaches a predefined current density threshold. Thus, the JFET is in the conducting state when the current density in the JFET is equal to or higher than the predefined current density threshold, and the drive voltage Vgs equals the threshold voltage when the current density has reached the predefined current density threshold.

According to one example, the current density is given by the load current Ids through the JFET 1 divided by a size of an active region of the JFET. The current density threshold is dependent on the specific implementation of the JFET 1. According to one example, the current density threshold is between 10 mA/mm² (10 mA (milliamperes) per 1 mm² size of the active region) and 100 mA/mm² (100 mA per 1 mm² size of the active region). The “size of the active region” is the size of an area occupied by transistor cells of the JFET in a semiconductor body. Examples of transistor cells are explained herein further below.

The JFET is implemented as a silicon carbide (SiC) JFET or a silicon (Si) JFET, for example. The current density threshold of between 10 mA/mm² and 100 mA/mm², in particular, applies to a SiC JFET.

According to one example, the JFET is an N-type (N-channel) JFET. In this example, the threshold voltage is negative. The threshold voltage is in a range of between −5V and −30V, for example, so that a magnitude of the threshold voltage is in a range of between 5V and 30V, for example.

In the conducting state, the JFET is configured to conduct a current through the load path. In the blocking state, the JFET is configured to block as long as a load path voltage Vds across the load path is lower than a rated blocking voltage of the JFET. The rated blocking voltage is dependent on a dimensioning of the device and is in the range of several 100 V, such as between 400 V and 800 V. The rated blocking voltage is the highest permissible load path voltage Vds at which the JFET safely blocks. In the blocking state, at most a leakage current may flow through load path. The leakage current is in a range of between several nanoamperes (nA) and several microamperes (uA), for example.

The JFET has a drain-source-capacitance. The drain-source-capacitance is an internal capacitance of the JFET that is effective between the drain and source terminals D, S. For illustration purposes, in FIG. 1, the drain-source-capacitance is represented by a first capacitor 11 connected between the drain and source terminals D, S. Furthermore, the JFET has a gate-drain-capacitance. The gate-drain-capacitance is also an internal capacitance of the JFET. For illustration purposes, in FIG. 1, the gate-drain-capacitance is represented by a second capacitor 12 connected between the gate terminal G and the drain current terminal D. The drain-source-capacitance 11 and the gate-drain-capacitance 12 together form an output capacitance of the JFET. In a superjunction JFET (in the same way as in a superjunction MOSFET), the output capacitance is non-linear. This means that a capacitance value Coss of the output capacitance is dependent on the load path voltage Vds. Furthermore, the capacitance value of the output capacitance decreases as the load path voltage Vds increases.

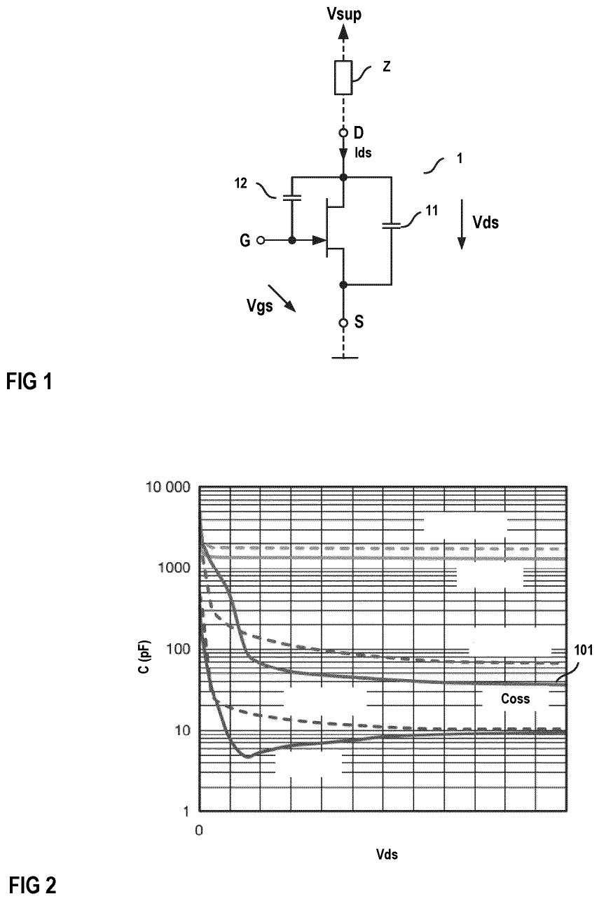

The characteristic curve of such a non-linear output capacitance is illustrated in FIG. 2 and labeled with 101. The diagram in FIG. 2 is semi-logarithmic. As can be seen from the characteristic curve 101, the capacitance value Coss initially decreases very quickly when the device is blocking and the load path voltage Vds starts to increases from zero. After this quick decrease, the capacitance value Coss decreases only very slowly as the load path voltage Vds further increases.

The superjunction JFET has a depletion charge. The depletion charge is the integral of the capacitance value Coss of the output capacitance over a range of the load path voltage Vds between zero to the rated blocking voltage. The depletion charge is the electrical charge that flows out of the device (or, dependent on the view, that flows into the device) when the load path voltage Vds increases from zero to the rated blocking voltage. With reference to the device according to FIG. 1, the depletion charge is the charge stored in the drain-source-capacitance 11 plus the charge stored in the gate-drain-capacitance 12 when the load path voltage Vds equals the rated blocking voltage of the JFET.

The superjunction JFET has a depletion voltage. The depletion voltage equals that voltage value (voltage level) of the load path voltage Vds at which 80% of the depletion charge have flown out of the JFET (or into the JFET).

According to one example, a magnitude of the depletion voltage is lower than 4 times of the magnitude of the threshold voltage. According to one example, the magnitude of the depletion voltage is lower than 3 times, lower than 2 times, or lower than 1.5 times of the magnitude of the threshold voltage. According to one example, the depletion voltage is lower than the magnitude of the threshold voltage.

According to a further example, a dimensioning of the superjunction JFET 1 is such that its depletion voltage is lower than 50 V and, in particular, lower than 40 V, lower than 30 V, or even lower than 20 V.

Implementing the superjunction JFET 1 such that the depletion voltage is related to the threshold voltage in accordance with one of the examples outlined above or is lower than 50 V helps to reduce losses when the superjunction JFET is in operation. This is explained in the following.

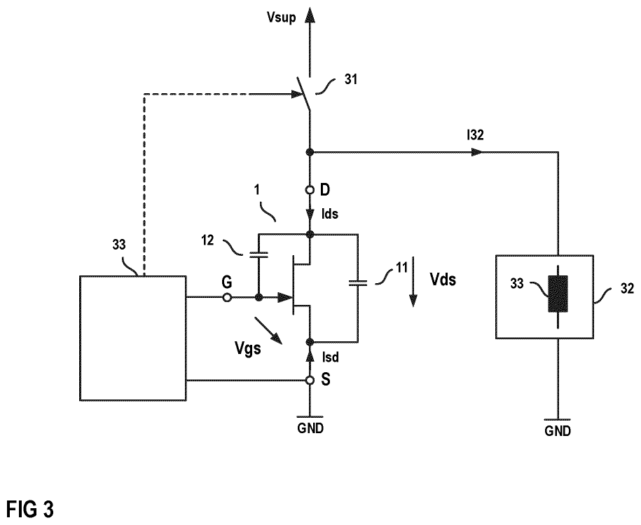

FIG. 3 illustrates an application circuit that includes a superjunction JFET 1 of the type illustrated in FIG. 1. In the circuit illustrated in FIG. 3, the superjunction JFET 1 is a low-side switch of a half-bridge. The superjunction JFET 1 acting as the low-side switch is connected in series with a high-side switch 31. The series circuit including the superjunction JFET 1 acting as the low-side switch and the high-side switch 31 is connected between supply terminals between which a supply voltage Vsup is available. A load 32, Such as an inductive load, is connected in parallel with the JFET 1. The JFET 1 is driven by a drive circuit 33, for example. The high-side switch 31, which can be any type of electronic switch, may be controlled by the same drive circuit 33 or by any other suitable drive circuit.

According to one example, the inductive load 32 includes at least one inductor 33. According to one example (not illustrated), the inductive load 32 and the half-bridge form a buck converter. In this example, the inductive load 33 includes an output capacitor that is connected in series with the inductor 33 and across which an output voltage is available. The inductor 33 and the output capacitor form a series circuit that is connected in parallel with the load path of the JFET 11.

According to one example, the high-side switch 31 and the JFET 1 are alternatingly driven in the conducting state and the blocking state. That is, the high-side switch 31 and the JFET 1 are switched on and off alternatingly. This includes that the high-side switch 31 is conducting when the JFET 1 is blocking, and vice versa. When the high-side switch 31 is conducting and the JFET 1 is blocking, the supply voltage Vsup drops across the load 32. When the high-side switch is 31 is blocking and the JFET 1 is conducting the, the JFET 1 acts as a freewheeling element or synchronous rectifier which enables a current I32 through the inductive load 32 to continue to flow after the high-side switch 31 has been switched off. In this operating mode, a current I32 through the inductive load 32 continues to flow in a direction as indicated by the arrow in FIG. 3, and a source-drain current Isd flows through the JFET in a direction as indicated by the arrow in FIG. 3.

According to one example, in order to avoid a cross current through the half-bridge, there is a dead time between switching off the high-side switch 31 and switching on the JFET 1 acting as the low-side switch. Switching on the JFET 1, as explained above, includes adjusting a voltage level of the drive voltage Vgs to be higher than the threshold voltage of the JFET. In the off-state of the JFET 1, the voltage level of the drive voltage is lower than the threshold voltage. If, for example, the threshold voltage is −10V, the voltage level of the drive voltage Vgs is between −15 V and −18V to safely maintain the JFET 1 in the off-state.

During the dead time, that is, when the JFET 1 is in the off-state, the JFET 1 may already take over the current I32 flowing through the inductor 33. In this operating state, the inductor 33 causes the electrical potential at the drain node of the JFET 1 to decrease such that the gate-drain voltage, which is the voltage between the gate node G and the drain node D becomes higher than the negative threshold voltage of the transistor devices, which causes the JFET 1 to conduct. In this operating state, the JFET is controlled by the gate-drain voltage instead of the gate-source voltage. If, for example, the gate-source voltage Vgs is −18V in the off-state and the threshold voltage is −10V, the JFET 1 starts to conduct when the inductive load 33 decreases the electrical potential at the drain node to about −8V related to the electrical potential at the source node S.

When the JFET 1 switches on by adjusting the gate-source voltage to be higher than the (negative) threshold voltage the JFET 1 is in the on-state and continues to conduct the current 32 through the inductive load 33.

As explained above, switching off the JFET is associated with a current flow (depletion current) that charges the output capacitance. This current flow causes losses. Basically, the higher the voltage across the circuit path in which the current associated with the charging process flows the higher the losses.

Assume that in an electronic circuit of the type illustrated in FIG. 3 the JFET 1 is a conventional JFET. In this example, a majority of the depletion current flows in the load branch, which is the circuit branch that includes the half-bridge. That is, the load branch is the circuit branch that includes the high-side switch 31 and the JFET 1 acting as the low-side switch connected in series and across which the supply voltage Vsup is available. The supply voltage Vsup may be in the range of several 100 V.

It is desirable to provide a JFET in which such losses are reduced. This is achieved by implementing the superjunction JFET 1 such that the threshold voltage and the depletion voltage are adapted to one another such that the magnitude of the depletion voltage is less than 4 times the magnitude of the threshold voltage, less than 3 times the magnitude of the treasured voltage, less than 2 times (twice) the magnitude of the threshold voltage, less than 1.5 times or even less than the magnitude of the threshold voltage, or I implementing the superjunction JFET 1 such that the threshold voltage is less than 50 V.

With this dimensioning of the superjunction MOSFET 1 a large portion of the depletion current associated with the depletion charge can flow via the gate terminal G (and the drive circuit 33), so that this current does not flow via the load branch across which a significantly higher voltage is available and where this current would cause significantly higher losses.

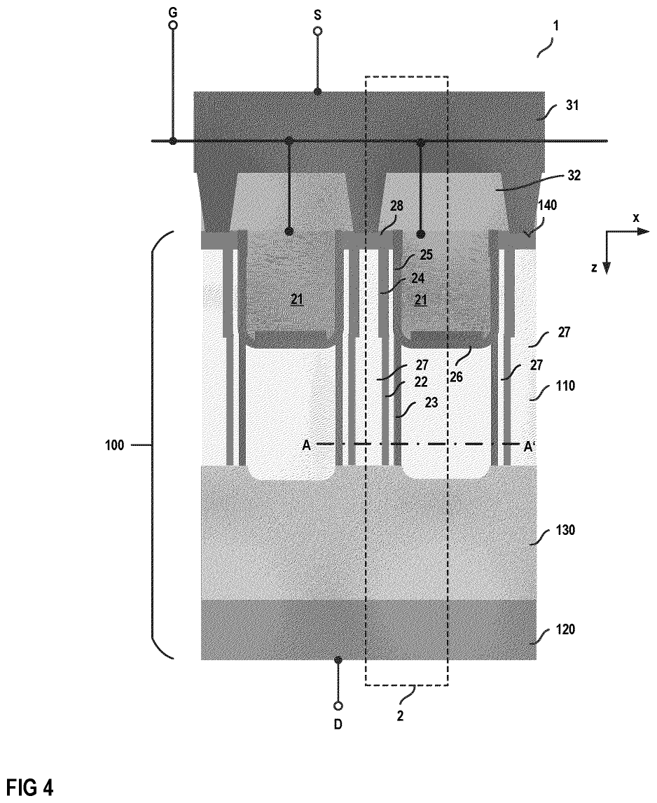

FIG. 4 shows a cross-sectional view of a superjunction JFET 1 which, with regard to its depletion voltage, can be dimensioned in accordance with one of the examples explained herein before. More specifically, FIG. 4 shows a cross-sectional view of a semiconductor body 100 in which active regions of the superjunction JFET 1 are integrated.

According to one example, the superjunction JFET 1 is a silicon carbide (SiC) superjunction JFET. In this example, the semiconductor body 100 is a SiC semiconductor body. According to another example, the superjunction JFET 1 is a silicon (Si) JFET, so that the semiconductor body 100 is a silicon semiconductor body.

As illustrated in FIG. 4, the superjunction JFET 1 includes several transistor cells that each include a doped first region 22 of a first doping type and a doped second region 23 of a second doping type. The first and second regions are arranged next to each other in a first lateral direction x of the semiconductor body 100. Furthermore, each transistor cell 2 includes a gate electrode 21 connected to the gate terminal G. Connections between the gate electrodes 21 and the gate terminal G are only schematically illustrated in FIG. 4.

The JFET 1 is an N-type JFET (N-channel JFET) for example. In this example, the first regions 22 are N-type (N-doped) regions and the second regions 23 are P-type (P-doped) regions. According to another example, the JFET 1 is a P-type JFET (P-channel JFET). In this example, the first and second regions 22, 23 have a doping type that is complementary to the doping type of the first and second doped regions 22, 23 of an N-type JFET.

The first regions 22 are ohmically coupled between the source terminal S and the drain terminal D of the JFET 1. This includes that the first regions 22 are ohmically connected to the source terminal S and the drain terminal D. This includes that between the first regions 22 and the source terminal S on one side and the drain terminal D on the other side there is no PN junction.

In the example illustrated in FIG. 4, the first and second regions 22, 23 are arranged in a first semiconductor layer 110 which may have a basic doping of the first doping type. Between the first and second regions 22, 23 regions 27 having the basic doping of the first semiconductor layer 110 may be arranged. These regions are referred to as a basic regions in the following. According to one example, the first and second regions 22, 23 and the basic regions 27 form a drift region of the JFET 1.

The basic doping of the first semiconductor layer 110 is less than 8E14 cm⁻³, for example. According to one example, the drain terminal D is connected to a second semiconductor layer 120 of the first doping type or is formed by this second semiconductor layer 120. The second semiconductor layer 120 may also be referred to as drain region of the JFET 1. A doping concentration of the second semiconductor layer 120 is higher than a doping concentration of the first semiconductor layer 110. According to one example, the doping concentration of the second semiconductor layer 120 is higher than 1E18 cm⁻³. Optionally, a third semiconductor layer 130 of the first doping type is arranged between the first semiconductor layer 110 and the second semiconductor layer 120, wherein a doping concentration of the third semiconductor layer 130 is between a doping concentration of the first semiconductor layer 110 and a doping concentration of the second semiconductor layer 120. The doping concentration of the third semiconductor layer 130 is between 1E16 cm⁻³ und 1E17 cm⁻³, for example.

In the example illustrated in FIG. 4, the first regions 22 adjoin the third semiconductor layer 130 and are connected to the second semiconductor layer 120 and the drain terminal D via the third semiconductor layer 130. The first semiconductor layer 110 with the first and second doped regions 22, 23 arranged therein and the optional third semiconductor layer 130 form a drift region of the superjunction JFET 1.

A vertical dimension of the first semiconductor layer 110 is between 1 micrometer (μm) and 5 micrometers, for example. A vertical dimension of the third semiconductor layer 130 is between 1 micrometer (μm) and 15 micrometers, for example.

Referring to FIG. 4, the JFET 1 includes a source electrode 31 arranged above the first surface 140 of the semiconductor body 100. The source electrode 31 is connected to the source terminal S or forms the source terminal S. The device according to FIG. 4 is a vertical device. This includes that the source electrode 31 and the second semiconductor layer 120 forming the drain terminal D or connected to the drain terminal D are spaced apart from each other in a vertical direction z of the semiconductor body 100.

The “vertical direction” is the direction in which the source electrode 31 and the second semiconductor layer 120 are spaced apart from each other and is essentially perpendicular to the first surface 140. The vertical dimension of the semiconductor layers 110, 130 explained above is the dimension of the respective layer 110, 130 in the vertical direction z of the semiconductor body 100. The vertical direction z is perpendicular to the first lateral direction x in which the first and second regions 22, 23 are arranged next to each other.

Referring to FIG. 4, the first regions 22 are connected to the source electrode 31. For this purpose, the first regions 22, in the vertical direction z, may extend to the source electrode 31. In this example, portions of the first regions 22 form source regions of the JFET.

Optionally, as illustrated in FIG. 4, the first regions 22 are connected to the source electrode 31 via doped third regions 24 of the first doping type and source regions 28 of the first doping type. The third regions 24 may have a higher or lower area related charge than the first doped regions 22. The “area related charge” of a doped region, such as a first region 22, a second region 23, or a third region 24 is given by the integral of the doping concentration of the respective region in the first lateral direction x. The area related charge is given by the amount of dopant atoms per square centimeters (cm⁻²).

The third regions 24 connect the first regions 22 to the source regions 28 that are connected to the source electrode 31. The third regions 24 are also referred to as first connection regions 24 in the following.

According to one example the area related charges of the first and second regions 22, 23 are selected such that the respective area related charge is between 30% and 90%, in particular, between 40% and 80%, of the critical area related charge of the semiconductor material of the semiconductor body 100. In silicon carbide (SiC) the critical area related charge is between 1.5E13 cm⁻² und 2E13 cm⁻², for example.

In the example illustrated in FIG. 4, the gate electrodes 21 are arranged in trenches which extend from the first surface 140 into the semiconductor body 100. More specifically, the gate electrodes 21 are arranged in trenches which extend from the first surface 140 into the first semiconductor layer 110. The third doped regions (first connection regions) 24, are doped regions arranged in mesa regions of the semiconductor body 100 between neighboring trenches, for example. In this example, the drift region with the first and second doped regions 22, 23 is arranged in regions of the semiconductor body 100 that are located below the gate electrodes 21 in the vertical direction z.

In each transistor cell 2, the second region 23 is ohmically connected to the gate electrode 21 of the respective transistor cell 2 (wherein, as illustrated, two transistor cells may share one gate electrode). In the example illustrated in FIG. 4, the second doped regions 23 are connected to the gate electrodes 21 via doped fourth regions 25 of the second doping type. In the example illustrated in FIG. 4, the fourth regions 25 adjoin the gate electrodes 21 in the mesa regions. According to one example, the fourth regions 25 have a higher area related charge than the second doped regions 23. As the fourth regions 25 connect the second regions 23 to the gate electrodes 21, the fourth regions 25 are also referred to as second connection regions in the following.

According to one example, the area related charge of the fourth doped regions (second connection regions) 25 is high enough for the fourth doped regions 25 not to be entirely depletable when the device is in the blocking state. In this example, the area related charge of the fourth doped regions 25 is higher than the critical area related charge of the semiconductor material of the fourth doped regions 25.

The gate electrodes 21 are a separated from regions of the first semiconductor layer 110 having the first doping type by doped regions of the second doping type. These doped regions of the second doping type may include the second connection regions 25 explained above. In the example illustrated in FIG. 4, the second connection regions 25 extend along sidewalls of the gate trenches that include the gate electrodes 21. In this example, doped fifth regions 26 of the second doping type, extend along the bottoms of the gate trenches and separate the gate electrodes 21 from doped regions of the first doping type along the bottoms of the gate trenches. The first region 26 may also be referred to as bottom regions. According to one example, a doping concentration of the bottom regions 26 is high enough for the bottom regions 26 not to be entirely depletable when the device is in the blocking state.

In the example illustrated in FIG. 4, the gate electrodes 21 may be elongated electrodes in a direction perpendicular to the drawing plane illustrated in FIG. 4, that is, perpendicular to the first lateral direction x. Equivalently, the first and second regions 22, 23, the first and second connection regions 24, 25, and the bottom regions 26 may be elongated regions in the direction perpendicular to the drawing plane.

According to another example (not illustrated) longitudinal directions of the gate electrodes 21, the first and second connection region 24, 25 arranged in the mesa regions, and the bottom regions 26 arranged below the gate trenches are perpendicular to longitudinal directions of the first and second doped regions 22, 23. In this example, longitudinal directions of the first doped regions 22 are perpendicular to longitudinal directions of the first connection regions 24 they adjoin, and longitudinal directions of the second doped regions 23 are perpendicular to longitudinal directions of the second connection regions 25 they adjoin. Furthermore, in this example each first region 22 adjoins a plurality of first connection regions 24, and each second region 23 adjoins a plurality of second connection regions 24.

The functionality of the JFET 1 illustrated in FIG. 4 is briefly explained in the following. When the device is in a conducting state, there is a conducting channel between the source terminal S and the drain terminal D via the source electrode 31, the first regions 22 and the optional first connection regions 24, the optional third semiconductor layer 130, and the second semiconductor layer 120.

When the device is in a blocking state by applying a suitable voltage between the gate terminal G and the source terminal S, the at least one first doped regions 22 or the at least one optional first connection regions 24 arranged in each mesa region between two neighboring gate electrodes 21 is pinched off in the mesa region, so that the conducting channel between the source terminal S and the drain terminal D is interrupted. As the load path voltage between the drain terminal D and the source terminal S increases, an electric field propagates in the horizontal direction (first lateral direction x). This electric field is associated with the first and second doped regions 22, 23 depleting each other, as is usual in superjunction devices. The mesa regions that are arranged between neighboring gate electrodes may be referred to as channel regions of the JFET 1.

In the example shown in FIG. 4, the first and second doped regions 22, 23 are arranged in such a way that, in the first lateral direction x, two first regions 22 are arranged next to each other, followed by two second regions 23. According to another example (not illustrated) the first and second regions 22, 23 are arranged alternatingly in the lateral direction x. In each case, a first region 22 is adjacent to a second region 23, so that the adjacent regions can deplete each other when the device is in the blocking state. Furthermore, between each pair of two neighboring first regions 22, each pair of two neighboring second regions 23 and each pair of two neighboring first and second regions 22, 23 a basic region 27 may be arranged. This, however, is only an example. According to one example, neighboring first and second regions 22, 23 adjoin one another.

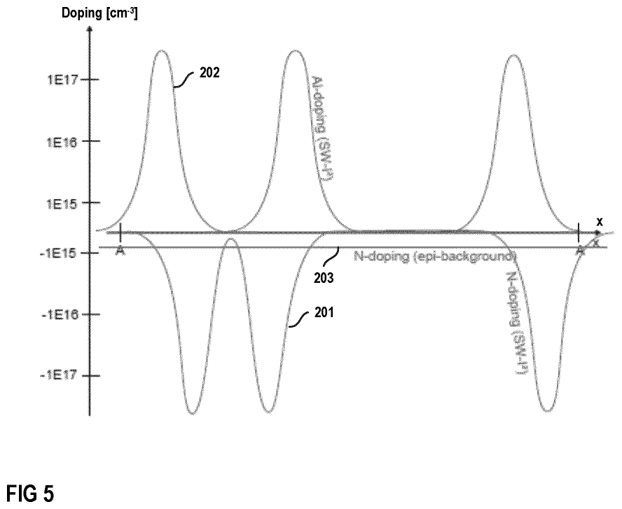

FIG. 5 schematically illustrates one example of a doping profile of the device illustrated in FIG. 4 along line A-A′ illustrated in FIG. 4. in FIG. 5, line 201 illustrates the doping concentration of the first regions 22, line 202 illustrates the doping concentration of the second doped regions 23, and line 203 illustrates the doping concentration of the basic doping of the first semiconductor layer 110. The fact that the first and second doped regions 22, 23 have complementary doping types is taken into account in FIG. 5 by the fact that the doping concentration of the first doped regions 22 (line 201) is drawn to be negative and the doping concentration of the second doped regions 23 (line 202) is drawn to be positive.

As mentioned above, the semiconductor body 100 is an SiC semiconductor body, for example. In a semiconductor body 100 of this type a P-type doping can be achieved, for example, by doping with aluminum (Al) or boron (B), and an N-type doping can be achieved, for example, by doping with nitrogen (N) or phosphorus (P).

According to another example, the semiconductor body 100 is a silicon (Si) semiconductor body.

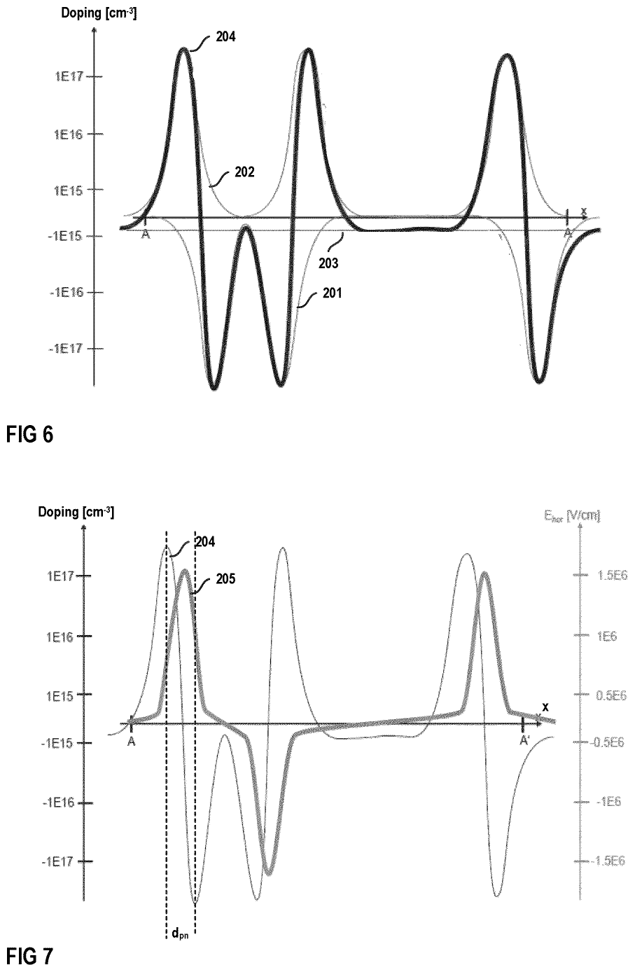

FIG. 6 illustrates the curves illustrated in FIG. 5 and an additional curve 204 that illustrates the effective doping (net doping) resulting from the doping of the first and second doping types illustrated by curves 201, 202, 203.

FIG. 7, in addition to the profile of the effective doping illustrated by curve 204 explained above, illustrates the electric field (see, line 205) resulting in the horizontal direction (that is, the first lateral direction x) when the device is blocking. As can be seen from FIG. 7, the maximum of the electric field in the first lateral direction x occurs where the doping type of the effective doping changes. The horizontal electric field Eₕₒᵣ reaches its maximum when each of the first and second doped regions 22, 23 his entirely depleted. The value (magnitude) of the maximum electric field is dependent on the area related charge in the first and second doped regions 22, 23.

Each semiconductor material has a critical electric field. The critical electric field denotes the value of the electric field at which an Avalanche breakdown occurs. The relationship between the maximum electric field and the critical electric field is the same as the relationship between the area relate charges of the first and second doped regions 22, 23 and the critical area related charge. If, for example, the area related charges in the first and second doped regions 22, 23 are 50% of the critical area charge, the maximum electric field is 50% of the critical electric field. Thus, the maximum electric field that occurs when the device is blocking can be adjusted via the area related charges of the first and second doped regions 22, 23.

As illustrated in FIG. 7, the electric field occurring in a region of two neighboring first and second regions 22, 23 has an essentially triangular profile. The depletion voltage is the integral in the first lateral direction x over a section of the electric field occurring in the region of two neighboring doped regions 22, 23. At a given maximum electric field (adjusted by the area charges of the first and second regions 22, 23), the shorter the extension of the first and second regions 22, 23 in the first lateral direction x the lower the integral.

According to one example, the first and second regions 22, 23 are formed such that the dimensions in the first lateral direction x are smaller than 500 nm, smaller than 400 nm, smaller than 300 nm, or smaller than 250 nm. The dimensions of the first regions 22 in the first lateral directions x correspond to the dimensions of those sections illustrated in the doping profile according to FIG. 6 that have a negative doping. Furthermore, the dimensions of the second doped regions 23 in the first lateral direction x correspond to the dimensions of those sections illustrated in the doping profile according to FIG. 6 that have a positive doping.

The dimensions of the first and second regions 22, 23 in the first lateral direction x at least approximately correspond to the distance, in the first lateral direction x, between peaks of the doping of two neighboring first and second regions 22, 23. In FIG. 7, dₚₙ denotes this distance. Those sections of the electric field that are formed in the region of two neighboring first and second regions 22, 23 are approximately triangular and, at the base, have a width which is about the width of the first regions 22 plus the width of the second regions 23 and, therefore, approximately twice the distance between two peaks. Thus, the depletion voltage can be calculated dependent on the maximum horizontal electric field E_{hor_max} approximately as follows:

$${V}_{dep} = \frac{1}{2} \cdot ( 2 \cdot dpn \cdot {E}_{hor \_ max} ) .$$

When, for example, dₚₙ=200 nm and E_{hor_max}=1.5 MV/cm, the depletion voltage is 30V.

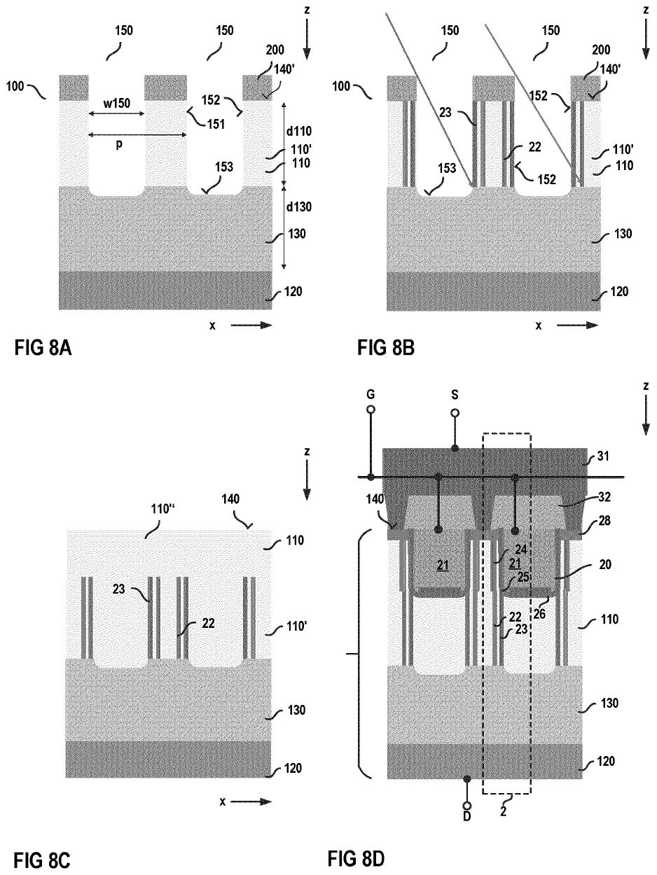

FIGS. 8A-8D illustrate one example of a method for forming a superjunction JFET with first and second regions 22, 23 that have dimensions in the first lateral direction x that are lower than the above-mentioned 500 nm. FIGS. 8A-8D each illustrate a cross-sectional view of one section of the semiconductor body 100 during different process steps of the method.

Referring to FIG. 8A, the method includes etching trenches 150 that extend from a surface 140′ into the semiconductor body 100. Etching the trenches 150 includes, for example, using an etch mask 200 formed on top of the first surface 140. Each of the trenches 150 includes a first sidewall 151, a second sidewall 152 opposite the first sidewall, and a bottom 153.

A width w150 of the trenches 150 in the first lateral direction x is between 0.5 micrometer (μm) and 2 micrometers, for example. A pitch p, which is a distance between corresponding sidewalls (between first sidewalls 151 or between second sidewalls 152) of two neighboring trenches 150 is between 2 micrometers and 3 micrometers, for example. According to one example, the trenches 150 are formed in a first portion 110′ of the first semiconductor layer 110. In the example illustrated in FIG. 8A, this first portion 110′ is an epitaxial layer that is either grown on the third semiconductor layer 130 (as illustrated) or that is grown on the second semiconductor layer 120. The surface 140′ in which the trenches 150 are formed is a horizontal surface of the first layout portion 110′.

Referring to FIG. 8A, the trenches 150 may be formed such that they completely extend through the first portion 110′ of the first semiconductor layer 110 either into the second semiconductor layer 120 or the optional third semiconductor layer 130 (as illustrated). As explained herein further below, the trenches 150 are used to implant first and second type dopant atoms into mesa regions separating the trenches 150. The trenches 150 may therefore be referred to as implantation trenches.

Referring to FIG. 8B, forming the first doped regions 22 of the first doping type includes implanting dopant atoms of the first doping type via the sidewalls 151, 152 of the trenches 150 into mesa regions between neighboring trenches 150, and forming the second doped regions 23 of the second doping type includes implanting dopant atoms of the second doping type via the sidewalls 151, 152 of the trenches 150 into the mesa regions. Implantation energies in the processes of implanting the dopant atoms of the first and second doping type are adapted to one another such that the first and second doped regions 22, 23 are arranged adjacent to each other after the implantation. Referring to FIG. 8B, dopant atoms of both the first and second doping type are implanted into each of the first and second sidewalls 151, 152 of the trenches 150.

Forming the first and second doped regions 22, 23 further includes a thermal process in which the semiconductor body 100, at least in the mesa regions, is heated up such that the implanted dopant atoms are activated. When SiC is used as a semiconductor material of the semiconductor body 100 this thermal activation process is not associated with a significant diffusion of the implanted dopant atoms, so that the dimensions of the resulting first and second doped regions 22, 23 in the first lateral direction x is essentially defined by the implantation process. The resulting small dimensions of the first and second doped regions 22, 23 in the first lateral direction x can be achieved by using essentially only one implantation energy in each implantation process. The value (magnitude) of the implantation energy can be used to adjust how deep the dopant atoms are implanted into the mesa regions in the first lateral direction x.

Referring to FIG. 8B, forming the first and second regions 22, 23 may include a first implantation process in which first type dopant atoms are implanted into the first sidewalls 151 of the trenches, a second implantation process in which second type dopant atoms are implanted into the first sidewalls 151 of the trenches 150, a third implantation process in which first type dopant atoms are implanted into the second sidewalls 152 opposite the first sidewalls 151 of the trenches 150, and a fourth implantation process in which second type dopant atoms are implanted into the second sidewalls 152 of the trenches 150. In the first and third implantation processes implanted regions are formed that include first type dopant atoms and based on which the first regions 22 are formed in the thermal process. In the second and fourth implantation processes implanted regions are formed that include second type dopant atoms and based on which the second regions are formed in the thermal process.

The etch mask 200 used for forming the trenches 150 may remain in place during the implantation processes. The implantation processes are tilted implantation processes, which are implantation processes in which an implantation angle, which is an angle between the implantation direction and the vertical direction z, deviates from zero. As illustrated in FIG. 8B, the implantation angle may be adjusted such that dopant atoms are implanted into each sidewall 151, 152 along the entire depth of the respective trench 150, but not into the trench bottom. In a conventional way the implantation angle may be adjusted dependent on the trench width w150, the trench depth and the thickness of the etch mask 200 in order to achieve that the dopant atoms are essentially implanted into the sidewalls 151, 152, only. The trench depth is the dimension of the trenches 150 in the vertical direction z.

Referring to FIG. 8C, the method further includes filling the trenches 150 with monocrystalline semiconductor material by forming a second portion 110″ of the first semiconductor layer 110 in an epitaxial process. The second portion 110″ fills the trenches 150 and may be grown on top of horizontal surfaces of the first portion 110′ outside the trenches 150, as illustrated in FIG. 8C. Thus, the first semiconductor layer 110 including the first and second layer portions 110′, 110″ may extend beyond the first and second doped regions 22, 23 in the vertical direction z of the semiconductor body 100. The first and second layer portions 110′, 110″ may be formed to have essentially the same basic doping.

FIG. 8D illustrates the finished device that is obtained from the structure illustrated in FIG. 8C by performing further processing steps. These processing steps include forming gate trenches 20 in the first semiconductor layer 110, and forming gate electrodes 21 in the gate trenches 20. After forming the gate trenches 20 and before forming the gate electrodes 21, the first and second connection regions 24, 25 and the bottom regions 26 may be formed. Forming the first connection regions 24 may include implanting first type dopant atoms into opposite sidewalls of the gate trenches 20 such that implanted regions are formed that adjoin the first regions 22, and an annealing process that activates the implanted dopant atoms. Forming the second connection region 25 may include implanting first and second dopant atoms into opposite sidewalls of the gate trenches 20 such that implanted regions are formed that adjoin the second regions 23, and an annealing process that activates the implanted dopant atoms. Forming the bottom regions 26 may include implanting the second type dopant atoms into bottoms of the gate trenches 20, and an annealing process that activate the implanted dopant atoms.

Furthermore, the further processing steps may include forming the source regions 28. This may include implanting dopant atoms of the first doping type into the first semiconductor layer 110, and an annealing process to activate the implanted dopant atoms. The dopant atoms may be implanted into the first semiconductor layer 110 via the first surface 140.

It should be noted that one annealing process for activating each of the implanted dopant atoms may be performed after the implantation processes have been finished. This may include the implantation processes for forming the first and second regions 22, 23 as well as the implantation processes for forming the first and second connection region 24, 25, the bottom regions 26, and the source regions 28

Optionally, before forming the gate trenches, a portion of the first semiconductor layer 110 is removed from above the first and second doped regions 22, 23. This may include simply planarizing the surface of the first semiconductor layer 110 or substantially removing portions of the first semiconductor layer 110.

In the event that there is no optional removal process, a horizontal surface of the second layer portion 110″ forms the first surface 140 of the semiconductor body 100. In the event that there is the optional removal process, a horizontal surface of the first semiconductor layer 110 after the removal process forms the first surface 140 of the semiconductor body 100.

Some of the aspects explained above are briefly summarized in the following with reference to numbered examples.
Example 1. A superjunction JFET comprising a threshold voltage and a depletion voltage, wherein a magnitude of the depletion voltage is lower than 4 times of the magnitude of the threshold voltage.
Example 2. Superjunction JFET according to example 1, wherein the magnitude of the depletion voltage is lower than 3 times, lower than 2 times, lower than 1.5 times of the magnitude of the threshold voltage or is lower than the magnitude of the threshold voltage.
Example 3. The superjunction JFET comprising a depletion voltage of less than 50 V.
Example 4. The superjunction JFET according to example 3, wherein the depletion voltage is less than 40 V or less than 30 V.
Example 5. The superjunction JFET according to any one of examples 1 to 4, wherein the superjunction JFET comprises a rated blocking voltage and a depletion charge, wherein the depletion charge is the electric charge that flows out of the superjunction JFET when the superjunction JFET changes from a conducting state to a blocking state and a load path voltage between a drain terminal and a source terminal of the superjunction JFET increases from zero to the rated blocking voltage, and wherein the depletion voltage equals to the load path voltage at which 80% of the depletion charge have flown out of the superjunction JFET.
Example 6. The superjunction JFET according to any one of examples 1 to 5, wherein the superjunction JFET is configured to receive a drive voltage and conduct a load current that is associated with a current density, and wherein the threshold voltage equals a voltage level of the drive voltage at which the current density associated with the load current reaches a current density threshold.
Example 7. The superjunction JFET according to example 6, wherein the current density threshold is between 10 mA/mm² and 100 mA/mm².
Example 8. The superjunction JFET according to any one of the examples 1 to 7, further comprising: a semiconductor body; a plurality of transistor cells each comprising a gate electrode, a first doped region of a first doping type and a second doped region of a second doping type arranged next to each other in a first lateral direction of the semiconductor body, wherein the first doped region is ohmically connected between a source terminal and a drain terminal of the superjunction JFET, and wherein the second doped region is ohmically connected to the gate electrode.
Example 9. The superjunction JFET according to example 8, wherein the gate electrodes are arranged in gate trenches that are spaced apart from each other and separated from each other by mesa regions of the semiconductor body, and wherein each transistor cell further comprises: a source region arranged in the mesa region and connected to the source terminal; and a first connection region of the first doping type connecting the first region to the source region.
Example 10. The superjunction JFET according to example 8 or 9, wherein each of the first doped region and the second doped region has an area charge in an area perpendicular to the first lateral direction, wherein, in each case, the area charge is between 30% and 90%, in particular between 50% and 80%, of a critical area charge of the semiconductor material of the semiconductor body.
Example 11. The superjunction JFET according to any one of examples 1 to 10, wherein the superjunction JFET is a silicon (Si) superjunction JFET.
Example 12. The superjunction JFET according to any of examples 1 to 10, wherein the superjunction JFET is a silicon carbide (SiC) superjunction JFET.
Example 13. The superjunction JFET according to example 12, wherein a dimension of each of the first and second doped regions in the first lateral direction (x) is less than 500 nanometers.
Example 14. The superjunction JFET according to example 13, wherein a dimension of each of the first and second doped regions in the first lateral direction is less than 400 nanometers, less than 300 nanometers, or less than 250 nanometers.
Example 15. An electronic circuit, comprising: a superjunction JFET according to any one of examples 1 to 12; an electronic switch connected in series with a drain-source path of the superjunction JFET; and an inductive circuit connected in parallel with the drain-source path of the superjunction JFET.
Example 16. A method, comprising: forming implantation trenches in a semiconductor body such that the trenches are spaced apart from each other in a first lateral direction of the semiconductor body and separated from each other by semiconductor mesa regions; forming a first region of a first doping type in each of the mesa regions using a first implantation process; forming a second region of a second doping type complementary to the first doping type using a second implantation process; filling the implantation trenches with a monocrystalline semiconductor material in an epitaxial growth process; forming gate trenches in the semiconductor body; forming further regions of the second doping type along sidewalls and bottoms of the gate trenches such that each second region adjoins at least one further region; and forming gate electrodes in the gate trenches.
Example 17. The method according to example 16, wherein the first implantation process comprises implanting dopant atoms of the first doping type into first sidewalls of the implantation trenches, wherein the second implantation process comprises implanting dopant atoms of the second doping type into the first sidewalls of the implantation trenches, and wherein implantation energies in the first and second implantation processes are adapted to one another such that the first region and the second region are arranged next to each other in the first lateral direction.
Example 18. The method according to example 16 or 17, further comprising: forming a further first region of the first doping type in each of the mesa regions using a third implantation process; and forming a further second region of the second doping type in each of the mesa regions using a fourth implantation process, wherein the third implantation process comprises implanting dopant atoms of the first doping type into second sidewalls opposite the first sidewalls of the implantation trenches, wherein the fourth implantation process comprises implanting dopant atoms of the second doping type into the second sidewalls of the implantation trenches, and wherein implantation energies in the third and fourth implantation processes are adapted to one another such that the further first region and the further second region are arranged next to each other in the first lateral direction.
Example 19. The method according to any one of examples 16 to 18, further comprising: forming a source electrode ohmically connected to the first regions above a surface of the semiconductor body.
Example 20. The method according to example 19, wherein forming the source electrode comprises forming the source electrode to adjoin the first regions.
Example 21. The method according to example 19, wherein the method further comprises. forming source regions of the first doping type in mesa regions between the gate trenches, and forming first connection regions of the first doping type in the mesa regions such that each first connection region adjoins at least one of the first regions, and wherein forming the source electrode comprises forming the source electrode to adjoin the source regions.
Example 22. The method according to any one of examples 16 to 21, wherein forming the first regions comprises forming the first regions to adjoin a semiconductor layer of the first doping type.

1-22. (canceled)

23. A superjunction JFET (junction field-effect transistor), comprising:
a threshold voltage; and
a depletion voltage,
wherein a magnitude of the depletion voltage is lower than 4 times a magnitude of the threshold voltage.

24. The superjunction JFET of claim 23, wherein the magnitude of the depletion voltage is lower than 3 times, lower than 2 times, lower than 1.5 times the magnitude of the threshold voltage, or is lower than the magnitude of the threshold voltage.

25. The superjunction JFET of claim 23, further comprising:
a depletion voltage of less than 50 V.

26. The superjunction JFET of claim 25, wherein the depletion voltage is less than 40 V or less than 30 V.

27. The superjunction JFET of claim 23, further comprising:
a rated blocking voltage; and
a depletion charge,
wherein the depletion charge is the electric charge that flows out of the superjunction JFET when the superjunction JFET changes from a conducting state to a blocking state and a load path voltage between a drain terminal and a source terminal of the superjunction JFET increases from zero to the rated blocking voltage,
wherein the depletion voltage equals to the load path voltage at which 80% of the depletion charge has flown out of the superjunction JFET.

28. The superjunction JFET of claim 23, wherein the superjunction JFET is configured to receive a drive voltage and conduct a load current that is associated with a current density, and wherein the threshold voltage equals a voltage level of the drive voltage at which the current density associated with the load current reaches a current density threshold.

29. The superjunction JFET of claim 28, wherein the current density threshold is between 10 mA/mm² and 100 mA/mm².

30. The superjunction JFET of claim 23, further comprising:
a semiconductor body; and
a plurality of transistor cells each comprising a gate electrode, a first doped region of a first doping type and a second doped region of a second doping type arranged next to each other in a first lateral direction of the semiconductor body,
wherein the first doped region is ohmically connected between a source terminal and a drain terminal of the superjunction JFET,
wherein the second doped region is ohmically connected to the gate electrode.

31. The superjunction JFET of claim 30, wherein the gate electrodes are arranged in gate trenches that are spaced apart from each other and separated from each other by mesa regions of the semiconductor body, and wherein each transistor cell further comprises:
a source region arranged in the corresponding mesa region and connected to the source terminal; and
a first connection region of the first doping type connecting the first doped region to the source region.

32. The superjunction JFET of claim 30, wherein each of the first doped region and the second doped region has an area charge in an area perpendicular to the first lateral direction, wherein in each case, the area charge is between 30% and 90% of a critical area charge of the semiconductor material of the semiconductor body.

33. The superjunction JFET of claim 32, wherein a dimension of each of the first doped region and the second doped region in the first lateral direction is less than 500 nanometers.

34. The superjunction JFET according to claim 33, wherein the dimension of each of the first doped region and the second doped region in the first lateral direction is less than 400 nanometers, less than 300 nanometers, or less than 250 nanometers.

35. The superjunction JFET of claim 23, wherein the superjunction JFET is a silicon superjunction JFET.

36. The superjunction JFET of claim 23, wherein the superjunction JFET is a silicon carbide superjunction JFET.

37. An electronic circuit, comprising:
the superjunction JFET of claim 23;
an electronic switch connected in series with a drain-source path of the superjunction JFET; and
an inductive circuit connected in parallel with the drain-source path of the superjunction JFET.

38. A method, comprising:
forming a plurality of implantation trenches in a semiconductor body such that the implantation trenches are spaced apart from each other in a first lateral direction of the semiconductor body and separated from each other by semiconductor mesa regions;
forming a first region of a first doping type in each of the semiconductor mesa regions using a first implantation process;
forming a second region of a second doping type complementary to the first doping type using a second implantation process;
filling the implantation trenches with a monocrystalline semiconductor material in an epitaxial growth process;
forming a plurality of gate trenches in the semiconductor body;
forming a plurality of further regions of the second doping type along sidewalls and bottoms of the gate trenches, such that each second region adjoins at least one further region; and
forming a gate electrode in each of the gate trenches.

39. The method of claim 38, wherein the first implantation process comprises implanting dopant atoms of the first doping type into first sidewalls of the implantation trenches, wherein the second implantation process comprises implanting dopant atoms of the second doping type into the first sidewalls of the implantation trenches, and wherein implantation energies in the first and second implantation processes are adapted to one another such that the first region and the second region are arranged next to each other in the first lateral direction.

40. The method of claim 38, further comprising:
forming a further first region of the first doping type in each of the semiconductor mesa regions using a third implantation process; and
forming a further second region of the second doping type in each of the semiconductor mesa regions using a fourth implantation process,
wherein the third implantation process comprises implanting dopant atoms of the first doping type into second sidewalls opposite the first sidewalls of the implantation trenches,
wherein the fourth implantation process comprises implanting dopant atoms of the second doping type into the second sidewalls of the implantation trenches,
wherein implantation energies in the third and fourth implantation processes are adapted to one another, such that the further first region and the further second region are arranged next to each other in the first lateral direction.

41. The method of claim 39, further comprising:
forming a source electrode ohmically connected to the first regions above a surface of the semiconductor body.

42. The method of claim 41, wherein forming the source electrode comprises forming the source electrode to adjoin the first regions.

43. The method of claim 41, further comprising:
forming a plurality of source regions of the first doping type in the semiconductor mesa regions between the gate trenches; and
forming a plurality of first connection regions of the first doping type in the semiconductor mesa regions, such that each first connection region adjoins at least one of the first regions,
wherein forming the source electrode comprises forming the source electrode to adjoin the source regions.

44. The method of claim 38, wherein forming the first regions comprises forming the first regions to adjoin a semiconductor layer of the first doping type.
